(19) United States
(12) Patent Application Publication
(10) Pub. No.: US 2008/0157302 A1
(43) Pub. Date: Jul. 3, 2008

(54) Stacked-package quad flat null lead package

(76) Inventors: SeungJu Lee, NamYangJu-Si (KR); Nelson Punzalan, Kaohsiung City (TW); KwanYong Chung, Seoul (KR)

Correspondence Address: BUCKLEY, MASCHOFF & TALWALKAR LLC, 50 LOCUST AVENUE, NEW CANAAN, CT, 06840, US

(21) Appl. No.: 11/646,048

(22) Filed: Dec. 27, 2006

(51) Int. Cl. H01L 23/495; H01L 21/00

(52) U.S. Cl. 257/676; 438/112; 257/E23.031; 257/E21.001

(57) ABSTRACT

A method, apparatus, and system relating to an IC package. The method includes providing a leadframe including a die pad for receiving a die and a plurality interconnect pillars, attaching a die to the die pad, bonding the die to the leadframe, and encapsulating the die and the leadframe to form a first IC package having a top surface and an opposing bottom surface, where the interconnect pillars extend from the top surface of the first IC package to the bottom surface of the first IC package.

### BACKGROUND

A number of conventional integrated circuit (IC) packages exist. Some IC packages may include more than one IC die. Some such packages may provide improved processing power per unit area and/or increased functionality per unit area. However, a failure of one die may result in lost functionality for the entire system. Some IC packages provide coupling multiple IC dice to each other and to various external elements. However, some such systems use solder bumps which may be susceptible solder joint failures and/or lengthy traces to interconnect the various dice.

### BRIEF DESCRIPTION OF THE DRAWINGS

FIG. 1 is an exemplary depiction of an apparatus, in accordance herewith;

FIG. 2 is a perspective top-side view of an apparatus, in accordance with some embodiments herein;

FIG. 3 is a perspective bottom-side view of an apparatus, in accordance with some embodiments herein;

FIGS. 4A-4D are illustrative of various stages of manufacture for an apparatus, according to some embodiments herein;

FIGS. 5-7 are illustrative of various device configurations, in accordance with some embodiments herein;

FIG. 8 is an exemplary depiction of an apparatus, in accordance with some embodiments herein; and

FIG. 9 is an exemplary diagram of a system 900, according to some embodiments.

### DETAILED DESCRIPTION

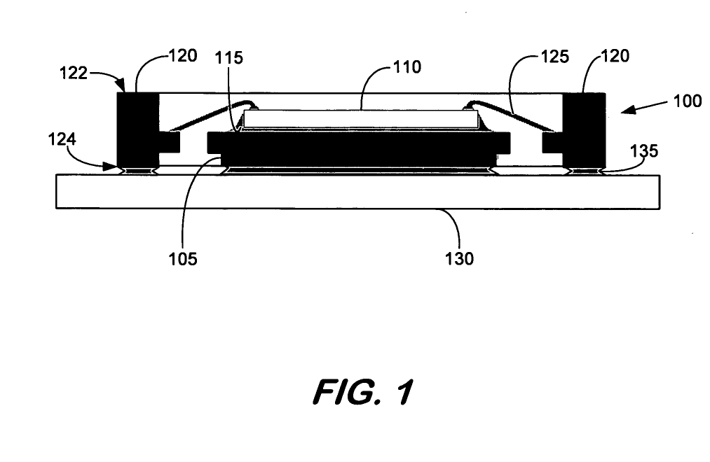

FIG. 1 is an exemplary depiction of an integrated circuit (IC) package 100, in accordance with some embodiments herein. In particular, FIG. 1 is an example of a Stacked-Package Quad Flat No-Lead (SPQFN) package. The structure of the package includes a leadframe having a die pad 105 and interconnecting pillars 120. The interconnecting pillars 120 extend from an upper surface of IC package 100 to a bottom surface of IC package 100, including an upper surface 122 and a bottom surface 124 of the interconnecting pillars. Die pad 145 is designed to carry die 110. Die 100 is adhered to leadframe 105 in a manner consistent with IC packaging processes. In some embodiments, die 110 is adhered to leadframe 105 by an adhesive material 115. A number of bonding wires 125 conductively connect the die to the leadframe at interconnecting pillars 120. IC package 100 further includes a molding compound 150 that encapsulates major portions of die pad 105 and interconnect pillars 120, leaving a terminal portion of die pad 145 and the upper surface 122 and lower surface 124 of the interconnect pillars exposed to an exterior of the IC package.

SPQFN package 100 is shown mounted to a PCB (printed circuit board) 130. SPQFN package 100 is conductively connected to PCB 130 by a conductive material 135 at disposed between SPQFN package 100 and PCB 130 at exposed locations of die pad 105 and interconnect pillars 120. In some embodiments, the conductive material is a conductive solder.

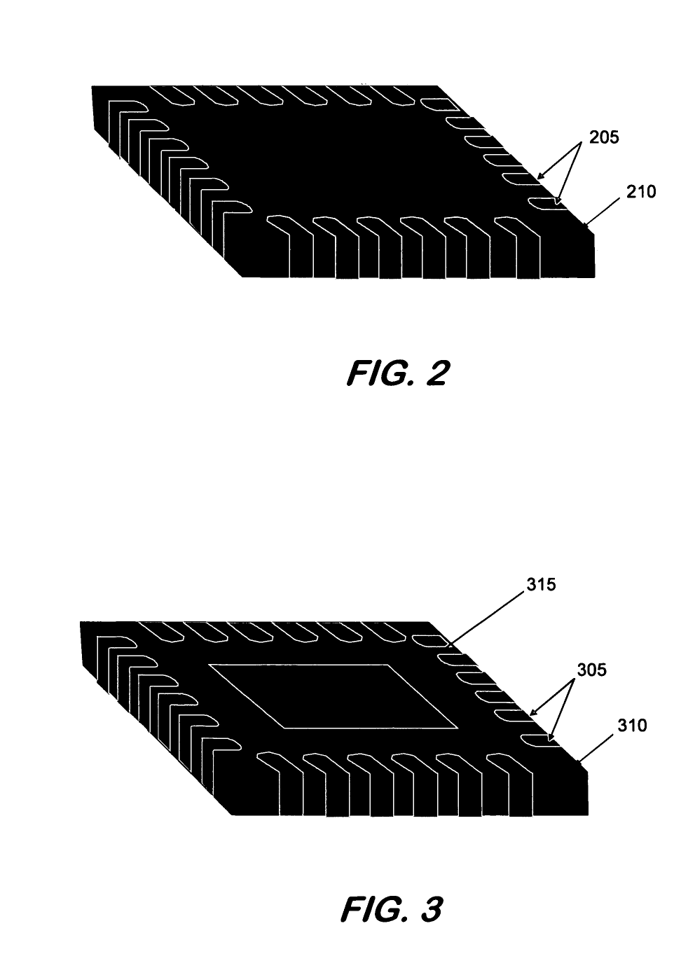

FIG. 2 is a perspective top-side view of an exemplary SPQFN package 200, in accordance with some embodiments herein. As shown, portions of interconnect pillars 205 are exposed to an exterior of the IC package and molding compound 210 encapsulates other portions of the IC package.

FIG. 3 is a perspective bottom-side view of an exemplary SPQFN package 300, in accordance with some embodiments herein. As shown, portions of interconnect pillars 305 and die pad 310 are exposed to an exterior of the IC package. Molding compound 310 encapsulates other portions of the IC package and completes the exterior structure of SPQFN package 300.

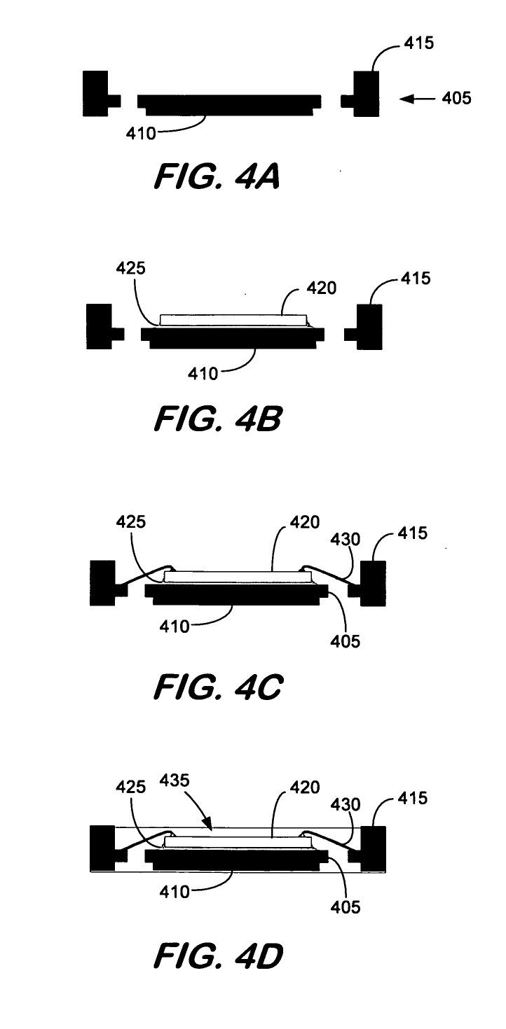

FIGS. 4A-4D illustrate an exemplary assembly of a SPQFN package of some embodiments herein. As shown in FIG. 4A, a method for forming the IC package includes providing a leadframe for receiving a die. The leadframe includes a die pad 410 and interconnect pillars 415.

FIG. 4B illustrates a stage of fabrication wherein a die 420 is adhered to die pad 410. Die 420 may be connected onto die pad 410 using an adhesive 425 such as, for example, a silver epoxy. In FIG. 4C die 420 is bonded to leadframe 405 by, for example, a number of bonding wires 430. Bonding wires 430 provide a conductive pathway between die 420 and leadframe 405, terminating at the interconnect pillars 415.

FIG. 4D illustrates a fully constructed SPQFN package, in accordance with some embodiments herein. FIG. 4 shows that die 420 and portions of the leadframe and interconnect pillars 415 are encapsulated in a molding material 435. Molding material 436 may include a resin. Molding material 435 acts to shield or protect the SPQFN package from external forces.

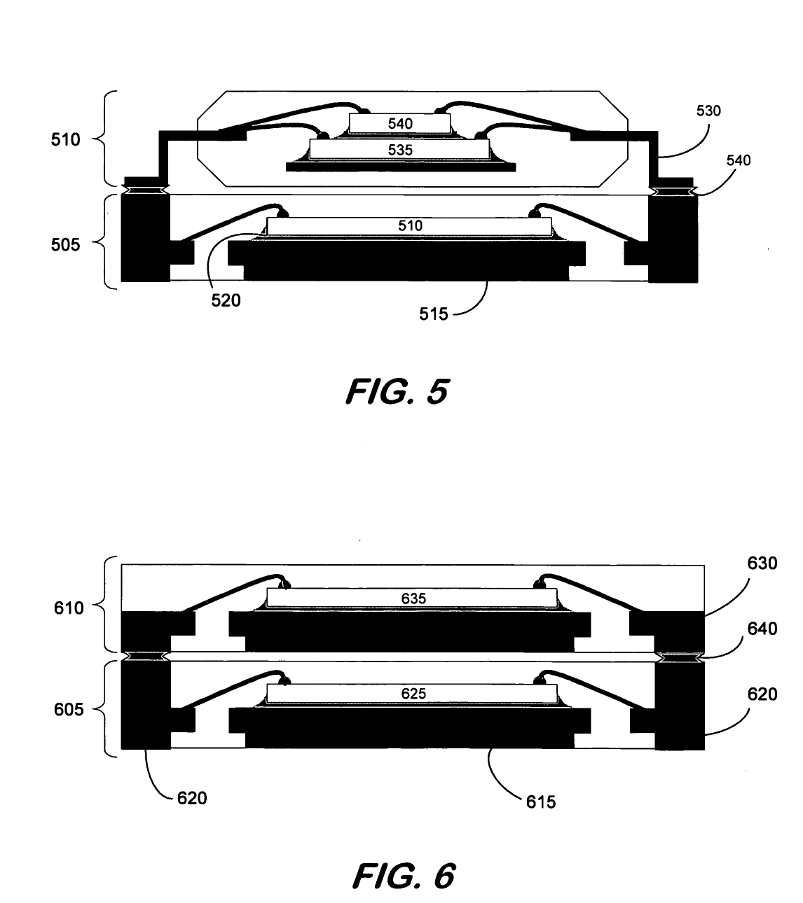

FIG. 5 is an illustrative depiction of an apparatus 500, in accordance with some embodiments herein. In particular, apparatus 500 includes a SPQFN package 505 having a die pad 515 and interconnect pillars 520 bonded to a die 525. IC package 510 is a TSOP (Thin Small-Outline Package) package having leads 530 bonded to dies 535 and 540. TSOP package 510 is stacked on top of SPQFN package 505. TSOP package 510 and SPQFN package 505 are conductively connected to each other by, for example, solder 540 at an interface of interconnect pillars 520 and leads 530.

FIG. 6 is an illustrative depiction of an apparatus 600, in accordance with some embodiments herein. In particular, apparatus 600 includes a SPQFN package 605 having a die pad 615 and interconnect pillars 620 bonded to a die 625. IC package 510 is a QFN package having bond pads 630 bonded to die 635. QFN package 610 is stacked on top of SPQFN package.605. QFN package 610 and SPQFN package 605 are conductively connected to each other by, for example, a conductive solder material 640 at an interface of interconnect pillars 620 and leads bonding pad 630.

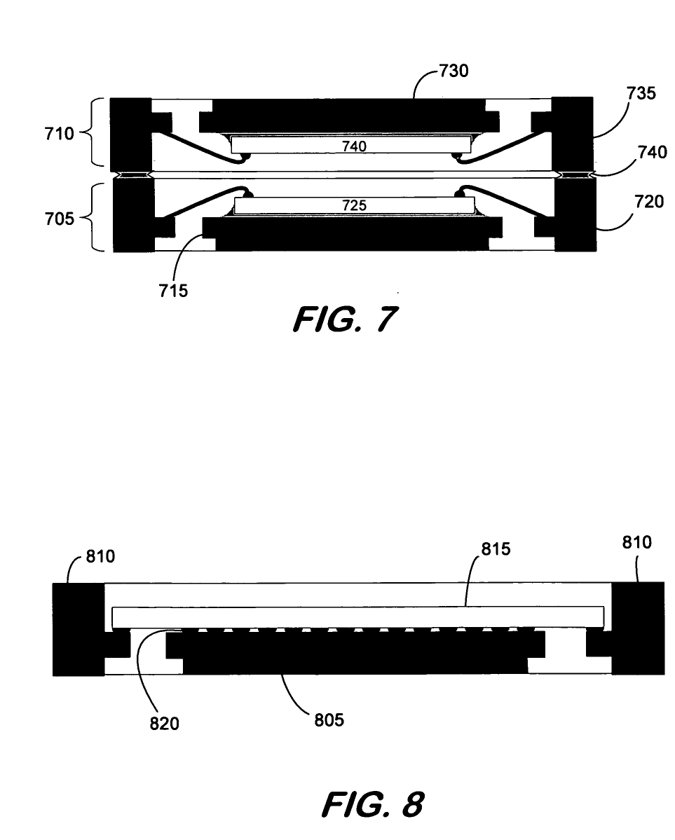

FIG. 7 is an illustrative depiction of an apparatus 700, in accordance with some embodiments herein. Apparatus 700 includes a first SPQFN package 705 having a die pad 715 and interconnect pillars 720 bonded to a die 720. A second SPQFN package having a die pad 730 and interconnect pillars 735 bonded to a die 740 is stacked on top of the first SPQFN package. SPQFN package 710 and SPQFN package 705 are conductively connected to each other by, for example, a conductive solder material 740 disposed between an interface of interconnect pillars 720 and 735 of the stacked SPQFN packages.

FIGS. 5, 6, and 7 illustrate how SPQFN packages disclosed herein may be stacked in combination with IC packages of various configurations, including other SPQFN packages. Such flexibility is provided, at least in part, by the interconnect pillars of the SPQFN package that are exposed for making connections to other devices and extend from the top surface of the SPQFN package to the bottom surface of the SPQFN package.

In some embodiments, the interconnect pillars of some SPQFN package devices herein may provide relatively short electrical path between connected IC packages. The interconnect pillars of the SPQFN package may provide a straight line connection to an IC package electrically connected to and stacked upon the SPQFN package.

FIG. 8 is an illustrative depiction of an apparatus 800, in accordance with some embodiments herein. Apparatus 800 illustrates that the structure of an SPQFN herein extends beyond the example wirebond technology of some of the embodiments shown. For example, flip chip technology may be included with a SPQFN. Apparatus 800 includes a leadframe having a die pad 805 and interconnect pillars 810. A flip chip including a die 815 and solder bumps 820 is attached to die pad 805. As illustrated, the SPQFN packages disclosed herein may offer flexibility with various technologies.

In some embodiments, the exposed die pad of the SPQFN package disclosed herein provides a mechanism for dissipating thermal energy generated by the IC package. Accordingly, some embodiments of the SPQFN package herein may have a higher thermal efficiency as compared to other types of IC packages.

In some embodiments, a device or system having multiple IC packages connected to each other, including at least one SPQFN constructed in accordance with the present disclosure, may have the individual IC packages tested prior to connecting the IC packages together. As such, functionality or compliance with operational specifications for each IC package may be confirmed prior to an assembly of the device or system including the multiple IC packages.

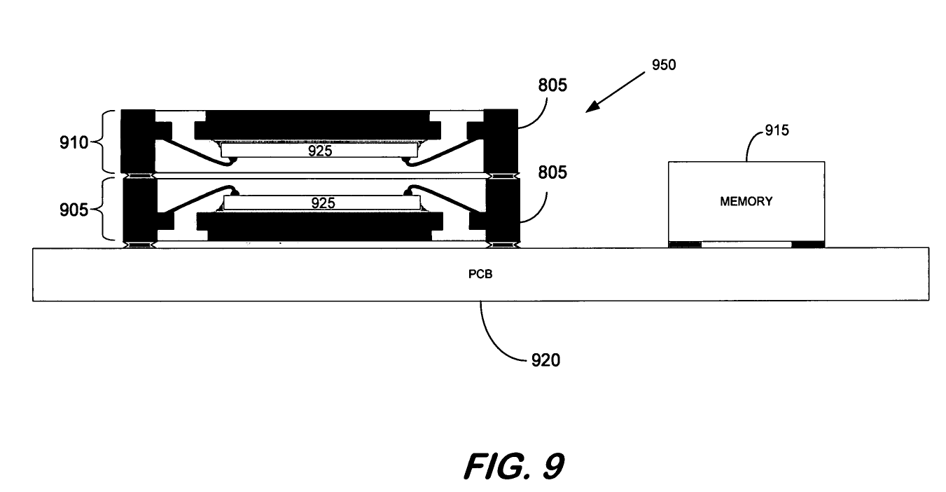

FIG. 9 is an exemplary schematic diagram of a system 900, according to some embodiments. System 900 includes an apparatus 950 that is similar to the apparatus 700 described hereinabove, a memory 915, and a PCB 920. Apparatus 950 includes a first SPQFN package 905 and a second SPQFN package 910 connected to and stacked atop the first SPQFN package. Both the first and the second SPQFN packages may include a leadframe having a die pad 925 and interconnect pillars 930 that extend from a top surface to a bottom surface of each of the their respective packages. Die 925 of each SPQFN may include a radio frequency (RF) module.

PCB 920 may electrically couple memory 915 to apparatus 950. More particularly, PCB 920 may comprise a bus (not shown) that is electrically coupled to apparatus 950 and to memory 915. Memory 915 may store, for example, applications, programs, procedures, and/or modules that store instructions to be executed by the microprocessor die of apparatus 950. Memory 915 may comprise, according to some embodiments, any type of memory for storing data, such as a Single Data Rate Random Access Memory (SDR-RAM), a Double Data Rate Random Access Memory (DDR-RAM), or a Programmable Read Only Memory (PROM).

The foregoing disclosure has been described with reference to specific exemplary embodiments thereof. It will, however, be evident that various modifications and changes may be made thereto without departing from the broader spirit and scope set forth in the appended claims.

What is claimed is:

1. A method, comprising:
providing a leadframe including a die pad for receiving a die and a plurality of interconnect pillars;
attaching a die to the die pad,
bonding the die to the leadframe; and
encapsulating the die and the leadframe to form a first IC package having a top surface and an opposing bottom surface, wherein the plurality of interconnect pillars extend from the top surface of the first IC package to the bottom surface of the first IC package.

2. The method of claim 1, further comprising singulating the first IC package from a wafer.

3. The method of claim 1, further comprising stacking a second IC package on the first IC package.

4. The method of claim 3, wherein the second IC package conductively connects to the first IC package by at least some of the the plurality of interconnect pillars of the first IC package.

5. The method of claim 3, wherein the second IC package is selected from the group consisting of: a Quad Flat No-Lead (QFN), a Thin Single Outline Package (TSOP), and an IC package including a leadframe having a die pad for receiving a die and a plurality of interconnect pillars, wherein the interconnect pillars extend from a top surface of the second IC package and an opposing bottom surface of the second IC package.

6. The method of claim 3, further comprising testing a functionality of the first IC package and a function of the second IC package prior to the stacking of the first and second IC packages.

7. The method of claim 1, wherein the die is bonded to the leadframe by at least one of a wire and a solder bump.

8. The method of claim 1, wherein the die pad of the first IC package has a bottom surface exposed to an exterior of the first IC package.

9. An apparatus, comprising:
a leadframe having a die pad for receiving a die and an interconnect pillar, wherein the die pad and the interconnect pillar are separated;
a die adhered to the die pad;
a bond between the die and the leadframe; and
a molding compound encapsulating the die and the leadframe to form a first IC package having a top surface and an opposing bottom surface, wherein the interconnect pillar extends from the top surface of the first IC package to the bottom surface of the first IC package.

10. The apparatus of claim 9, wherein the die is adhered to the leadframe by an adhesive.

11. The apparatus of claim 9, wherein the die is bonded to the leadframe by at least one of a wire and a solder bump.

12. The apparatus of claim 9, wherein the die pad of the first IC package has a bottom surface exposed to an exterior of the first IC package.

13. The apparatus of claim 9, further comprising a second IC package stacked on the first IC package.

14. The apparatus of claim 13, wherein the second IC package conductively connects to the first IC package by at least some of the interconnect pillars of the first IC package.

15. A system, comprising:
a leadframe having a die pad for receiving a die and a plurality of interconnect pillars, wherein the die pad and the interconnect pillars are separated;
a die adhered to the die pad;
a bond between the die and the leadframe;
a molding compound encapsulating the die and the leadframe to form a first IC package having a top surface and an opposing bottom surface, wherein the interconnect pillars extend from the top surface of the first IC package to the bottom surface of the first IC package; and
a second IC package comprising a radio frequency (RF) device, wherein the second IC package is conductively connected to the first IC package at the interconnect pillars of the first IC package.

16. The system of claim 15, wherein the second IC package comprises a leadframe having a die pad for receiving a die and a plurality of interconnect pillars, wherein the interconnect pillars extend from a top surface of the second IC package to an opposing bottom surface of the second IC package.

17. The system of claim 15, wherein the die is adhered to the leadframe by an adhesive.

18. The system of claim 15, wherein the die is bonded to the leadframe by at least one of a wire and a solder bump.

19. The system of claim 15, wherein the die pad of the first IC package has a bottom surface exposed to an exterior of the first IC package.

20. The system of claim 15, wherein the second IC package is stacked on the first IC package.
